(19) United States
(12) Patent Application Publication
(10) Pub. No.: US 2007/0111541 A1
(43) Pub. Date: May 17, 2007

(54) Barrier film material and pattern formation method using the same

(76) Inventors: Masayuki Endo, Osaka (JP); Masaru Sasago, Osaka (JP)

Correspondence Address: MCDERMOTT WILL & EMERY LLP, 600 13TH STREET, N.W., WASHINGTON, DC, 20005-3096, US

(21) Appl. No.: 11/545,425

(22) Filed: Oct. 11, 2006

(30) Foreign Application Priority Data
Nov. 17, 2005 (JP) 2005-333305

(51) Int. Cl. H01L 23/58; H01L 21/31

(52) U.S. Cl. 438/780; 257/629

(57) ABSTRACT

In a pattern formation method, a barrier film including a polymer and a cross-linking agent for thermally causing a cross-linking reaction of the polymer is formed on a resist film formed on a substrate. Subsequently, the barrier film is annealed for cross-linking the polymer, and pattern exposure is performed by selectively irradiating the resist film with exposing light through the barrier film with a liquid provided on the barrier film. Then, after removing the barrier film, the resist film is developed after the pattern exposure. Thus, a resist pattern made of the resist film is formed.

### CROSS-REFERENCE TO RELATED APPLICATIONS

This application claims priority under 35 U.S.C. §119 on Patent Application No. 2005-333305 filed in Japan on Nov. 17, 2005, the entire contents of which are hereby incorporated by reference.

### BACKGROUND OF THE INVENTION

The present invention relates to a material for a barrier film formed on a resist film for use in immersion lithography in fabrication process or the like for semiconductor devices and a pattern formation method using the same.

In accordance with the increased degree of integration of semiconductor integrated circuits and downsizing of semiconductor devices, there are increasing demands. for further rapid development of lithography technique. Currently, pattern formation is carried out through photolithography using exposing light of a mercury lamp, KrF excimer laser, ArF excimer laser or the like, and use of F₂ laser lasing at a shorter wavelength is being examined. However, since there remain a large number of problems in exposure systems and resist materials, photolithography using exposing light of a shorter wavelength has not been put to practical use.

In these circumstances, immersion lithography has been recently proposed for realizing further refinement of patterns by using conventional exposing light (for example, see M. Switkes and M. Rothschild, “Immersion lithography at 157 nm”, J. Vac. Sci. Technol., Vol. B19, p. 2353 (2001)).

In the immersion lithography, a region in an exposure system sandwiched between a projection lens and a resist film formed on a wafer is filled with a liquid having a refractive index n (whereas n>1) and therefore, the NA (numerical aperture) of the exposure system has a value n·NA. As a result, the resolution of the resist film can be improved.

Also, in the immersion lithography, use of an acidic solution as an immersion liquid has been recently proposed for further improving the refractive index (see, for example, B. W. Smith, A. Bourov, Y. Fan, L. Zavyalova, N. Lafferty, F. Cropanese, “Approaching the numerical aperture of water—Immersion Lithography at 193 nm”, Proc. SPIE, Vol. 5377, p. 273 (2004)).

Now, a conventional pattern formation method employing the immersion lithography will be described with reference to FIGS. 19A through 19D, 20A and 20B.

First, a positive chemically amplified resist material having the following composition is prepared:

Base polymer: poly((norbornene-5-methylene-t-butylcarboxylate) (50 mol %)—(maleic anhydride) (50 mol %)) . . . 2 g

Acid generator: triphenylsulfonium trifluoromethane sulfonate . . . 0.05 g

Quencher: triethanolamine . . . 0.002 g

Solvent: propylene glycol monomethyl ether acetate . . . 20 g

Next, as shown in FIG. 19A, the aforementioned chemically amplified resist material is applied on a substrate 1 so as to form a resist film 2 with a thickness of 0.35 μm.

Then, as shown in FIG. 19B, by using a barrier film material having the following composition, a barrier film 3 having a thickness of 50 nm is formed on the resist film 2 by, for example, spin coating:

Base polymer: polyvinyl hexafluoroisopropyl alcohol . . . 1 g

Solvent: n-butyl alcohol . . . 20 g

Next, as shown in FIG. 19C, the resultant barrier film 3 is annealed with a hot plate at a temperature of 110° C. for 60 seconds.

Then, as shown in FIG. 19D, with an immersion liquid 4 of water provided on the barrier film 3, pattern exposure is carried out by irradiating the resist film 2 through the liquid 4 and the barrier film 3 with exposing light 5 of ArF excimer laser with NA of 0.68 having passed through a mask 6.

After the pattern exposure, as shown in FIG. 20A, the resist film 2 is baked with a hot plate at a temperature of 105° C. for 60 seconds, and the resultant resist film is developed with a 2.38 wt % tetramethylammonium hydroxide developer. In this manner, a resist pattern 2a made of an unexposed portion of the resist film 2 is formed as shown in FIG. 20B.

However, as shown in FIG. 20B, the resist pattern 2a obtained by the conventional pattern formation method is in a defective shape.

The present inventors have variously examined the reason why the resist pattern formed by the conventional immersion lithography is in a defective shape, resulting in finding the following: Since the immersion liquid 4 permeates into the resist film 2 through the barrier film 3 formed on the resist film 2 for protecting it from the immersion liquid 4, a water mark defect is caused in the resist film 2 after the pattern exposure. In FIG. 20B, the acid generator included in the resist film 2 is extracted into the liquid 4 due to a water mark defect caused in the resist film 2, and hence, the chemical amplification cannot be sufficiently caused through the pattern exposure and the post exposure bake. As a result, a bridge defect is caused.

When the resist pattern in such a defective shape is used for etching a target film, the resultant pattern of the target film is also in a defective shape, which disadvantageously lowers the productivity and the yield in the fabrication process for semiconductor devices.

### SUMMARY OF THE INVENTION

In consideration of the aforementioned conventional problem, an object of the invention is forming a fine resist pattern in a good shape by preventing an immersion liquid from permeating into a resist film through a barrier film formed for protecting the resist film from the immersion liquid.

The present inventors have found the following: When a polymer itself included in a barrier film used for protecting a resist film is thermally crosslinked, when the surface of a barrier film is subjected to a water-repellent treatment with fluorine plasma or when a water-repellent or waterproof film is formed on a barrier film, an immersion liquid does not permeate into the barrier film, and hence, a water mark defect is prevented from being caused in the resist film. This is probably because, in either case, the barrier film can attain a surface state for strongly repelling a liquid or preventing permeation of a liquid.

Specifically, the barrier film material of this invention is for use in forming a barrier film between a resist film and an immersion liquid when exposure of the resist film is performed with the immersion liquid provided above the resist film, and includes a polymer and a cross-linking agent for thermally causing a cross-linking reaction of the polymer.

According to the barrier film material of this invention, when a barrier film made of the present barrier film material is formed on a resist film and the resultant barrier film is annealed for causing the cross-linking reaction of the polymer, the permeability of the immersion liquid is largely lowered in the polymer cross-linked in the barrier film. Therefore, no water mark defect is caused in the resist film covered with the barrier film including the cross-linked polymer, and hence deterioration of the resist film otherwise caused by the liquid can be prevented. As a result, a fine pattern can be formed in a good shape.

In the barrier film material of the invention, the cross-linking agent may include a melamine compound or an epoxy compound.

In the barrier film material of the invention, the polymer may be polyvinyl alcohol, polyacrylic acid or polyvinyl hexafluoroisopropyl alcohol.

The first pattern formation method of this invention includes the steps of forming a resist film on a substrate; forming, on the resist film, a barrier film including a polymer and a cross-linking agent for thermally causing a cross-linking reaction of the polymer; annealing the barrier film for cross-linking the polymer by the cross-linking agent; performing pattern exposure by selectively irradiating the resist film through the barrier film with exposing light with a liquid provided on the barrier film; removing the barrier film; and forming a resist pattern made of the resist film by developing the resist film after removing the barrier film and after the pattern exposure.

In the first pattern formation method, the barrier film including the polymer and the cross-linking agent for thermally causing a cross-linking reaction of the polymer is formed on the resist film and then the barrier film is annealed to cross-link the polymer by using the cross-linking agent. Therefore, the permeability of the immersion liquid is largely lowered in the polymer cross-linked in the barrier film. Accordingly, no water mark defect is caused in the resist film covered with the barrier film including the cross-linked polymer, and hence deterioration of the resist film otherwise caused by the liquid can be prevented. As a result, a fine pattern can be formed in a good shape.

In the first pattern formation method of the invention, the cross-linking agent may include a melamine compound or an epoxy compound.

In the first pattern formation method of the invention, the polymer may be polyvinyl alcohol, polyacrylic acid or polyvinyl hexafluoroisopropyl alcohol.

The second pattern formation method of this invention includes the steps of forming a resist film on a substrate; forming a barrier film on the resist film; performing a water-repellent treatment for providing a water-repellent property to a surface of the barrier film; performing pattern exposure by selectively irradiating the resist film through the barrier film with exposing light with a liquid provided on the barrier film having been subjected to the water-repellent treatment; removing the barrier film; and forming a resist pattern made of the resist film by developing the resist film after removing the barrier film and after the pattern exposure.

In the second pattern formation method, the barrier film is subjected to the water-repellent treatment for providing a water-repellent property to the surface of the barrier film, and hence, the permeability of the immersion liquid is largely lowered in the barrier film having been subjected to the water-repellent treatment. Therefore, no water mark defect is caused in the resist film covered with the barrier film having been subjected to the water-repellent treatment, and hence deterioration of the resist film otherwise caused by the liquid can be prevented. As a result, a fine pattern can be formed in a good shape.

In the second pattern formation method, the barrier film is preferably exposed to plasma including fluorine in the step of performing a water-repellent treatment.

The third pattern formation method of this invention includes the steps of forming a resist film on a substrate; forming a barrier film on the resist film; forming a water-repellent film having a water-repellent property on the barrier film; performing pattern exposure by selectively irradiating the resist film through the water-repellent film and the barrier film with exposing light with a liquid provided on the water-repellent film; removing the water-repellent film; and removing the barrier film and forming a resist pattern made of the resist film by developing the resist film after removing the water-repellent film and after the pattern exposure.

The fourth pattern formation method of this invention includes the steps of forming a resist film on a substrate; forming a barrier film on the resist film; forming a water-repellent film having a water-repellent property on the barrier film; performing pattern exposure by selectively irradiating the resist film through the water-repellent film and the barrier film with exposing light with a liquid provided on the water-repellent film; removing the water-repellent film; removing the barrier film; and forming a resist pattern made of the resist film by developing the resist film after removing the barrier film and after the pattern exposure.

In the third or fourth pattern formation method, the water-repellent film having a water-repellent property is formed on the barrier film, and hence, the immersion liquid does not permeate into the resist film owing to the water-repellent film formed on the barrier film. Therefore, no water mark defect is caused in the resist film, and hence deterioration of the resist film otherwise caused by the liquid can be prevented. As a result, a fine pattern can be formed in a good shape.

In the third or fourth pattern formation method, the barrier film is preferably coated with a material including fluorine in the step of forming a water-repellent film.

In the third or fourth pattern formation method, the water-repellent film may include a polymer having fluorine in a principal chain.

In the third or fourth pattern formation method, the polymer may be a copolymer of tetrafluoroethylene.

The fifth pattern formation method of this invention includes the steps of forming a resist film on a substrate; forming a barrier film on the resist film; forming a waterproof film having a waterproof property on the barrier film; performing pattern exposure by selectively irradiating the resist film through the waterproof film and the barrier film with exposing light with a liquid provided on the waterproof film; removing the waterproof film; and removing the barrier film and forming a resist pattern made of the resist film by developing the resist film after removing the waterproof film and after the pattern exposure.

The sixth pattern formation method of this invention includes the steps of forming a resist film on a substrate; forming a barrier film on the resist film; forming a waterproof film having a waterproof property on the barrier film; performing pattern exposure by selectively irradiating the resist film through the waterproof film and the barrier film with exposing light with a liquid provided on the waterproof film; removing the waterproof film; removing the barrier film; and forming a resist pattern made of the resist film by developing the resist film after removing the barrier film and after the pattern exposure.

In the fifth or sixth pattern formation method, the waterproof film having a waterproof property is formed on the barrier film, and hence, the immersion liquid does not permeate into the resist film owing to the waterproof film formed on the barrier film. Therefore, no water mark defect is caused in the resist film, and hence deterioration of the resist film otherwise caused by the liquid can be prevented. As a result, a fine pattern can be formed in a good shape.

In the fifth or sixth pattern formation method, the waterproof film may include polyamide.

In this case, the polyamide may be a condensation polymer of ε-caprolactam, a co-condensation polymer of hexamethylene diamine and adipic acid or a co-condensation polymer of p-phenylene diamine and terephthalic acid.

Each of the second through sixth pattern formation methods preferably further includes, between the step of forming a barrier film and the step of performing pattern exposure, a step of annealing the banier film. Thus, the denseness of the barrier film can be improved, so that the barrier film can be more insoluble in the liquid provided thereon for the exposure. However, when the denseness of the barrier film is excessively improved, it becomes difficult to remove the barrier film by dissolving it, and hence, the barrier film should be annealed in an appropriate temperature range. For example, the temperature is preferably 100° C. or more and 150° C. or less, which does not limit the invention.

The barrier film used for protecting the resist film in this invention is removed before or during the development.

As a solvent for removing the barrier film, any of an organic solvent, a fluorine solvent, a developer, a diluted developer and the like can be used. Examples of the organic solvent are n-butyl alcohol, sec-butyl alcohol, t-butyl alcohol, isopropyl alcohol, n-amyl alcohol and isoamyl alcohol. Examples of the fluorine solvent are 1,1,2,3,3,3-hexafluoro-1-diethylamino propane and triethylamine tris-hydrofluoride.

With respect to the degree of dilution of the diluted developer, the concentration is lower than that of a general developer, that is, 2.38 wt % tetramethylammonium hydroxide and is, for example, 0.01% or more and 2% or less, which does not limit the invention.

For removing the barrier film of the first pattern formation method in which the polymer is thermally cross-linked and the barrier film of the second pattern formation method on which the water-repellent treatment is performed, an organic solvent or a fluorine solvent can be used.

The water-repellent film formed on the barrier film in the third or fourth pattern formation method and the waterproof film formed on the barrier film in the fifth or sixth pattern formation method may be removed before removing the barrier film. Also for removing the water-repellent film or the waterproof film, an organic solvent or a fluorine solvent may be used. Since the water-repellent film or the waterproof film is formed on the barrier film, the resist film can be advantageously prevented from being damaged in removing the water-repellent or waterproof film.

The barrier film of this invention may be removed during the development as in the third or fifth pattern formation method or before the development as in the fourth or sixth pattern formation method. Either case has its own advantage. First, when the barrier film is removed during the development of the resist film as in the third or fifth pattern formation method, the dissolution characteristic of the resist film can be controlled to be improved. In other words, when the barrier film is removed simultaneously with the development, the dissolution characteristic of the resist film can be controlled to some extent. Alternatively, when the barrier film is removed before the development as in the fourth or sixth pattern formation method, the subsequent development can be smoothly performed.

The dissolution characteristic of a resist film will now be described with reference to FIG. 21. In general, when the dissolution characteristic of a resist film is high, the dissolution rate is abruptly increased when exposure exceeds a given threshold value (a threshold region of FIG. 21) (as shown with a graph A of a broken line in FIG. 21). As the change of the dissolution rate against the exposure is more abrupt, a difference in the solubility between an exposed portion and an unexposed portion of the resist film is larger, and hence, the resist pattern can be formed in a better shape. Accordingly, in the case where the barrier film is removed simultaneously with the development, the dissolution rate is wholly lowered during the removal of the barrier film, and hence, the change in a portion surrounded with a circle C in FIG. 21 can be made flatter. As a result, in the case where the actual resist film has the dissolution characteristic as shown with a graph B, the dissolution rate attained with smaller exposure can be adjusted to attain a comparatively constant solution state with a low dissolution rate even if the small exposure is varied to some extent. Accordingly, the difference in the solubility between an exposed portion and an unexposed portion of the resist film can be easily caused, resulting in easily forming a resist pattern in a good shape.

In any of the first through sixth pattern formation methods, the liquid may be water.

Alternatively, in any of the first through sixth pattern formation methods, the liquid may be an acidic solution.

In this case, the acidic solution may be a cesium sulfate (Cs₂SO₄) aqueous solution or a phosphoric acid (H₃PO₄) aqueous solution. Furthermore, the liquid may further include an additive such as a surfactant.

In any of the first through sixth pattern formation methods, the exposing light may be KrF excimer laser, Xe₂ laser, ArF excimer laser, F₂ laser, KrAr laser or Ar₂ laser.

### BRIEF DESCRIPTION OF THE DRAWINGS

FIGS. 1A, 1B, 1C and 1D are cross-sectional views for showing procedures in a pattern formation method according to Embodiment 1 of the invention;

FIGS. 2A, 2B and 2C are cross-sectional views for showing other procedures in the pattern formation method of Embodiment 1;

FIGS. 3A, 3B, 3C and 3D are cross-sectional views for showing procedures in a pattern formation method according to Embodiment 2 of the invention;

FIGS. 4A, 4B, 4C and 4D are cross-sectional views for showing other procedures in the pattern formation method of Embodiment 2;

FIGS. 5A, 5B, 5C and 5D are cross-sectional views for showing procedures in a pattern formation method according to Embodiment 3 of the invention;

FIGS. 6A, 6B, 6C and 6D are cross-sectional views for showing other procedures in the pattern formation method of Embodiment 3;

FIGS. 7A, 7B, 7C and 7D are cross-sectional views for showing procedures in a pattern formation method according to Embodiment 4 of the invention;

FIGS. 8A, 8B, 8C and 8D are cross-sectional views for showing other procedures in the pattern formation method of Embodiment 4;

FIG. 9 is a cross-sectional view for showing another procedure in the pattern formation method of Embodiment 4;

FIGS. 10A, 10B, 10C and 10D are cross-sectional views for showing procedures in a pattern formation method according to Embodiment 5 of the invention;

FIGS. 11A, 11B, 11C and 11D are cross-sectional views for showing other procedures in the pattern formation method of Embodiment 5;

FIGS. 12A and 12B are cross-sectional views for showing other procedures in the pattern formation method of Embodiment 5;

FIGS. 13A, 13B, 13C and 13D are cross-sectional views for showing procedures in a pattern formation method according to Embodiment 6 of the invention;

FIGS. 14A, 14B, 14C and 14D are cross-sectional views for showing other procedures in the pattern formation method of Embodiment 6;

FIG. 15 is a cross-sectional view for showing another procedure in the pattern formation method of Embodiment 6;

FIGS. 16A, 16B, 16C and 16D are cross-sectional views for showing procedures in a pattern formation method according to Embodiment 7 of the invention;

FIGS. 17A, 17B, 17C and 17D are cross-sectional views for showing other procedures in the pattern formation method of Embodiment 7;

FIGS. 18A and 18B are cross-sectional views for showing other procedures in the pattern formation method of Embodiment 7;

FIGS. 19A, 19B, 19C and 19D are cross-sectional views for showing procedures in a conventional pattern formation method;

FIGS. 20A and 20B are cross-sectional views for showing other procedures in the conventional pattern formation method; and

FIG. 21 is a graph for explaining control of solubility of a resist in the pattern formation method of the invention.

### DETAILED DESCRIPTION OF THE INVENTION

EMBODIMENT 1

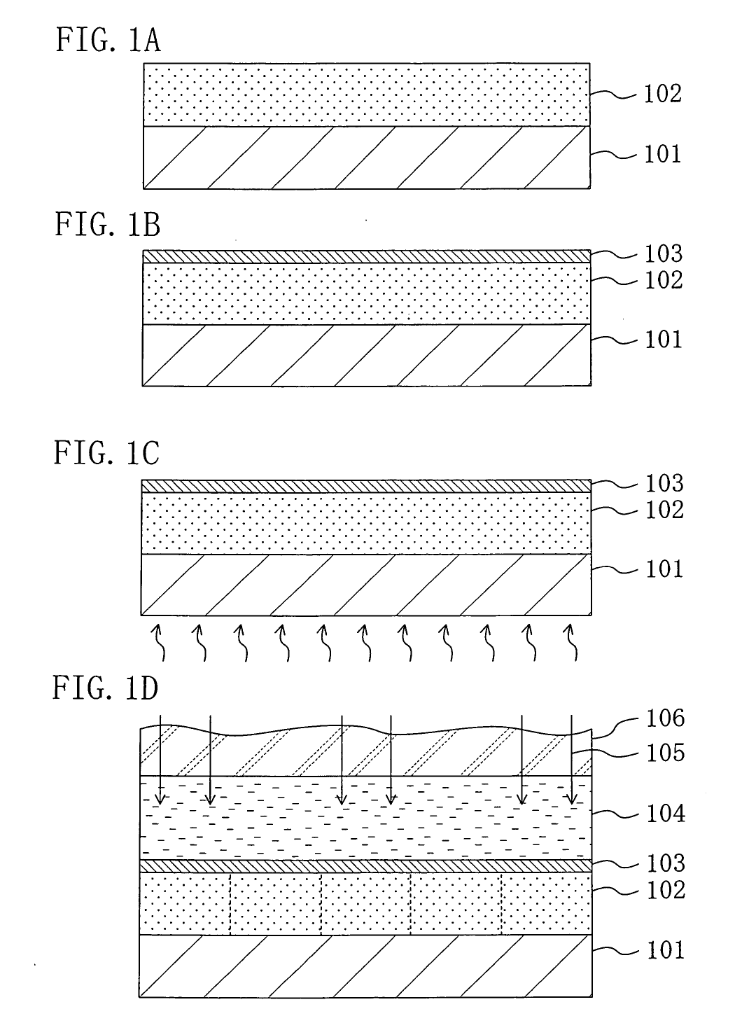

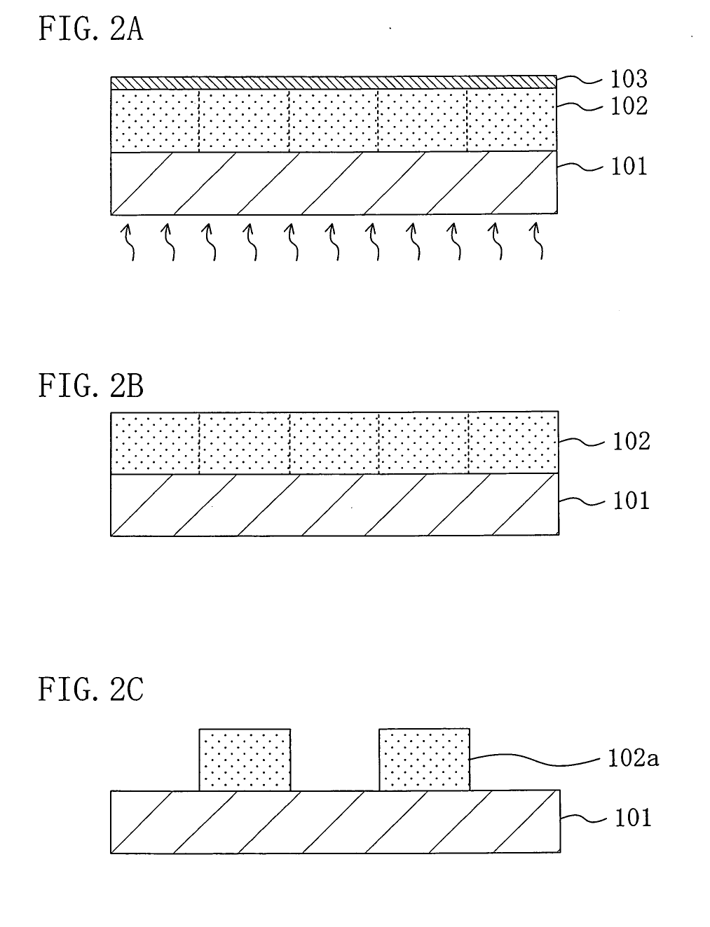

A pattern formation method according to Embodiment 1 of the invention will now be described with reference to FIGS. 1A through 1D and 2A through 2C.

First, a positive chemically amplified resist material having the following composition is prepared:

Base polymer: poly((norbornene-5-methylene-t-butylcarboxylate) (50 mol %)—(maleic anhydride) (50 mol %)) . . . 2 g

Acid generator: triphenylsulfonium trifluoromethane sulfonate . . . 0.05 g

Quencher: triethanolamine . . . 0.002 g

Solvent: propylene glycol monomethyl ether acetate . . . 20 g

Next, as shown in FIG. 1A, the aforementioned chemically amplified resist material is applied on a substrate 101 so as to form a resist film 102 with a thickness of 0.35 μm.

Then, as shown in FIG. 1B, by using a barrier film material according to this invention having the following composition, a barrier film 103 having a thickness of 60 nm is formed on the resist film 102 by, for example, spin coating:

Base polymer: polyvinyl hexafluoroisopropyl alcohol . . . 1 g

Cross-linking agent: 1,3,5-tri(hydroxymethyl)melamine . . . 0.1 g

Solvent: n-butyl alcohol . . . 20 g

Then, as shown in FIG. 1C, the resultant barrier film 103 is annealed with a hot plate at a temperature of 120° C. for 90 seconds, so as to improve the denseness of the barrier film 103.

After the annealing, as shown in FIG. 1D, with an immersion liquid 104 of water provided between the barrier film 103 and a projection lens 106 by, for example, a puddle method, pattern exposure is carried out by irradiating the resist film 102 through the liquid 104 and the barrier film 103 with exposing light 105 of ArF excimer laser with NA of 0.68 having passed through a mask (not shown).

After the pattern exposure, as shown in FIG. 2A, the resist film 102 is baked with a hot plate at a temperature of 105° C. for 60 seconds (post exposure bake).

Next, as shown in FIG. 2B, the barrier film 103 is removed by using, for example, n-butyl alcohol, and thereafter, the resultant resist film 102 is developed with a 2.38 wt % tetramethylammonium hydroxide developer. In this manner, a resist pattern 102a made of an unexposed portion of the resist film 102 and having a line width of 0.09 μm is formed in a good shape as shown in FIG. 2C.

In this manner, according to Embodiment 1, in the procedure for forming a barrier film shown in FIG 1B, the material for the barrier film 103 to be formed on the resist film 102 includes 1,3,5-tri(hydroxymethyl)melamine, that is, a thermal cross-linking agent. Therefore, in the procedure for pattern exposure shown in FIG. 1D, the cross-linking agent added to the base polymer of the barrier film 103 is heated so as to cause a cross-linking reaction therein, and hence, the liquid 104 can be prevented from permeating into the resist film 102. Accordingly, no water mark defect is caused by the liquid 104 in the resist film 102. As a result, deterioration of the resist film 102 otherwise caused through extraction of the acid generator or the like by the liquid 104 can be prevented, so that the resultant resist pattern 102a can be formed in a good shape.

Although a melamine compound of 1,3,5-tri(hydroxymethyl)melamine is used as the cross-linking agent in Embodiment 1, this does not limit the invention but a similar good result can be attained by using an epoxy compound such as epoxy methanol.

Furthermore, although polyvinyl hexafluoroisopropyl alcohol is used as the base polymer of the barrier film 103, polyvinyl alcohol or polyacrylic acid may be used instead.

EMBODIMENT 2

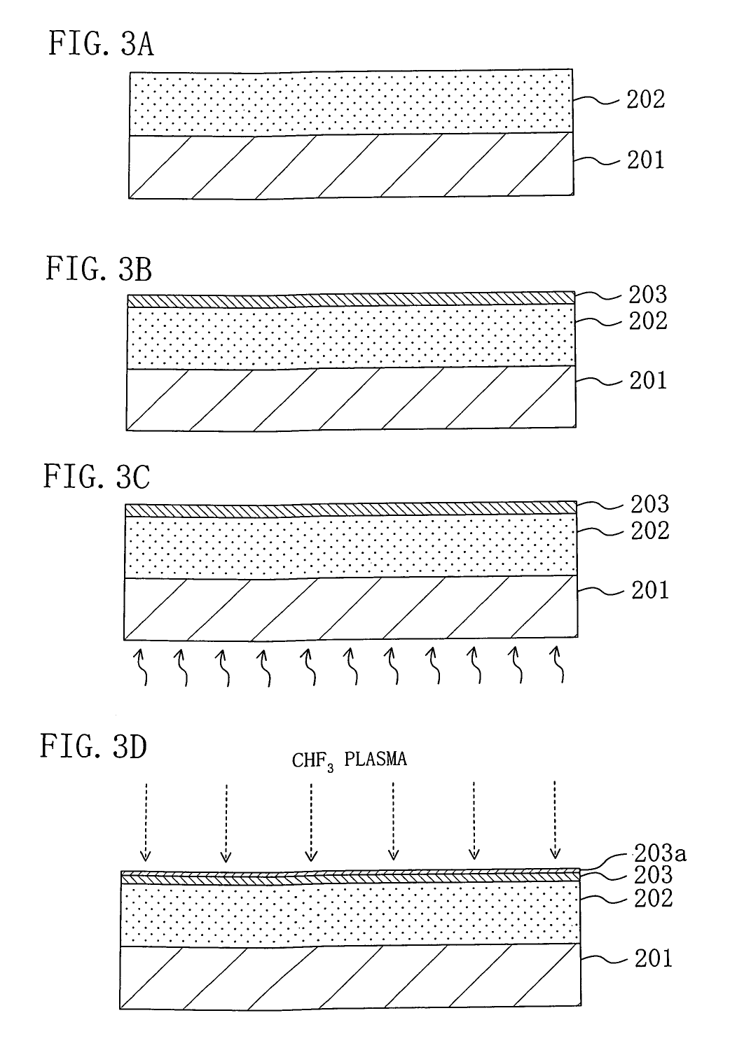

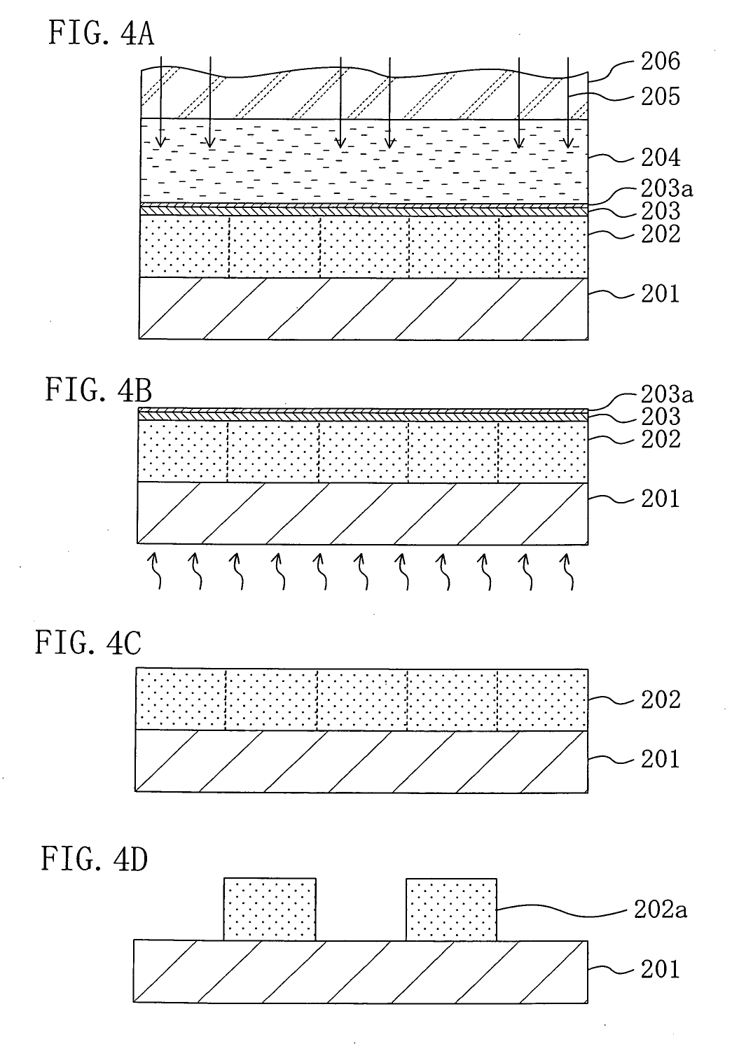

A pattern formation method according to Embodiment 2 of the invention will now be described with reference to FIGS. 3A through 3D and 4A through 4D.

First, a positive chemically amplified resist material having the following composition is prepared:

Base polymer: poly((norbornene-5-methylene-t-butylcarboxylate) (50 mol %)—(maleic anhydride) (50 mol %)) . . . 2 g

Acid generator: triphenylsulfonium trifluoromethane sulfonate . . . 0.05 g

Quencher: triethanolamine . . . 0.002 g

Solvent: propylene glycol monomethyl ether acetate . . . 20 g

Next, as shown in FIG. 3A, the aforementioned chemically amplified resist material is applied on a substrate 201 so as to form a resist film 202 with a thickness of 0.35 μm.

Then, as shown in FIG. 3B, by using a conventional barrier film material having the following composition, a barrier film 203 having a thickness of 50 nm is formed on the resist film 202 by, for example, the spin coating:

Base polymer: polyvinyl hexafluoroisopropyl alcohol . . . 1 g

Solvent: n-butyl alcohol . . . 20 g

Next, as shown in FIG. 3C, the resultant barrier film 203 is annealed with a hot plate at a temperature of 110° C. for 60 seconds, so as to improve the denseness of the barrier film 203.

Thereafter, as shown in FIG. 3D, the surface of the barrier film 203 is exposed to plasma of trifluoromethane (CHF₃) for 10 seconds as a water-repellent treatment. Thus, a fluorine adsorption layer 203a is formed on the barrier film 203 through adsorption of fluorine (F) atoms.

Next, as shown in FIG. 4A, with an immersion liquid 204 of water provided between the barrier film 203 having the fluorine adsorption layer 203a thereon and a projection lens 206 by, for example, the puddle method, pattern exposure is carried out by irradiating the resist film 202 through the liquid 204 and the barrier film 203 with exposing light 205 of ArF excimer laser with NA of 0.68 having passed through a mask (not shown).

After the pattern exposure, as shown in FIG. 4B, the resist film 202 is baked with a hot plate at a temperature of 105° C. for 60 seconds (post exposure bake).

Next, as shown in FIG. 4C, the barrier film 203 is removed by using, for example, triethylamine tris-hydrofluoride, and then, the resultant resist film 202 is developed with a 2.38 wt % tetramethylammonium hydroxide developer. In this manner, a resist pattern 202a made of an unexposed portion of the resist film 202 and having a line width of 0.09 μm is formed in a good shape as shown in FIG. 4D.

In this manner, according to Embodiment 2, in the procedure for a water-repellent treatment for a barrier film shown in FIG. 3D, the fluorine adsorption layer 203a is formed by using the fluorine plasma on the barrier film 203 provided on the resist film 202. Therefore, in the procedure for pattern exposure shown in FIG. 4A, the liquid 204 can be prevented from permeating into the resist film 202 by the fluorine adsorption layer 203a formed on the barrier film 203. Accordingly, no water mark defect is caused by the liquid 204 in the resist film 202. As a result, deterioration of the resist film 202 otherwise caused through extraction of the acid generator or the like by the liquid 204 can be prevented, so that the resultant resist pattern 202a can be formed in a good shape.

Although the triethylamine tris-hydrofluoride is used for removing the barrier film 203 having been subjected to the water-repellent treatment using the fluorine plasma in Embodiment 2, this does not limit the invention but 1,1,2,3,3,3-hexafluoro-1-diethylamino propane or the like may be used instead.

EMBODIMENT 3

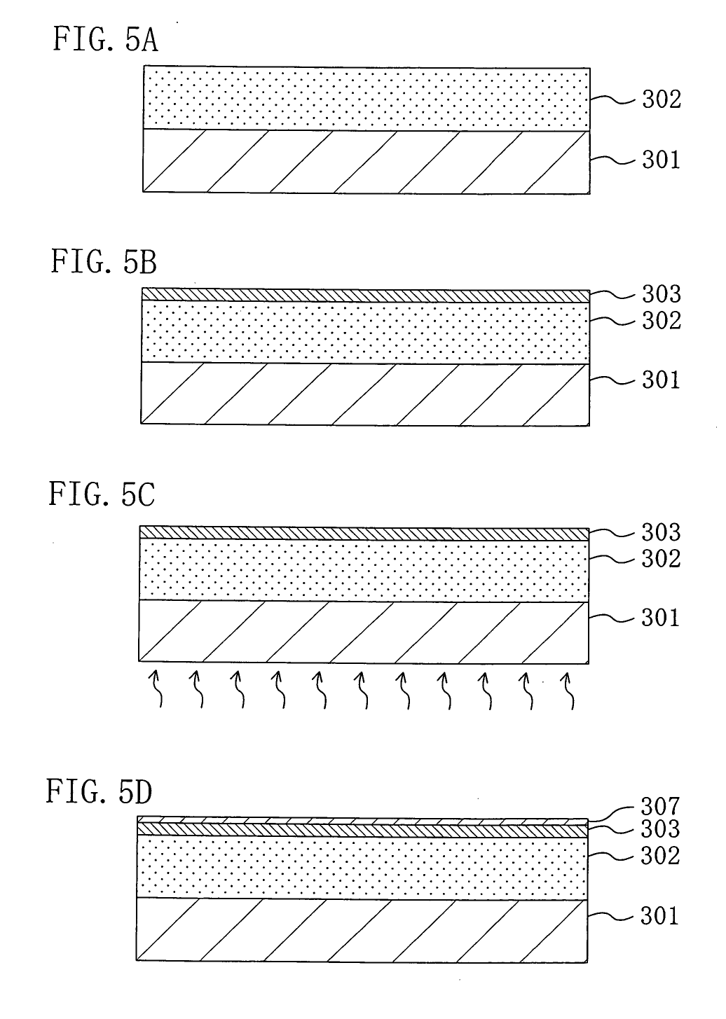

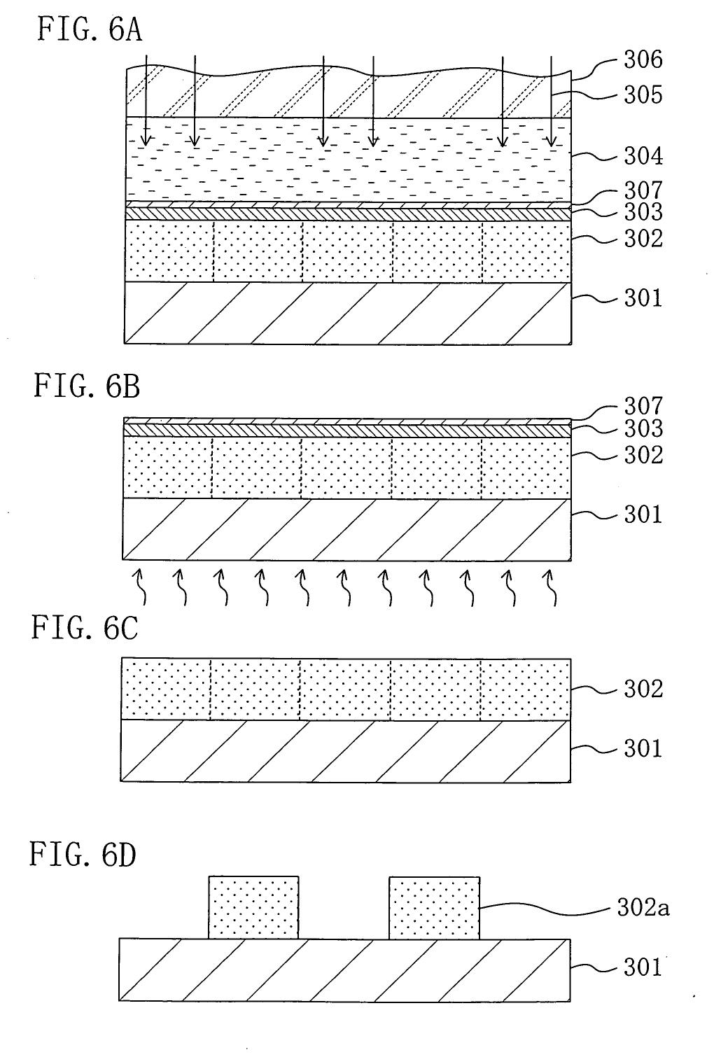

A pattern formation method according to Embodiment 3 of the invention will now be described with reference to FIGS. 5A through 5D and 6A through 6D.

First, a positive chemically amplified resist material having the following composition is prepared:

Base polymer: poly((norbornene-5-methylene-t-butylcarboxylate) (50 mol %)—(maleic anhydride) (50 mol %)) . . . 2 g

Acid generator: triphenylsulfonium trifluoromethane sulfonate . . . 0.05 g

Quencher: triethanolamine . . . 0.002 g

Solvent: propylene glycol monomethyl ether acetate . . . 20 g

Next, as shown in FIG. 5A, the aforementioned chemically amplified resist material is applied on a substrate 301 so as to form a resist film 302 with a thickness of 0.35 μm.

Then, as shown in FIG. 5B, by using a conventional barrier film material having the following composition, a barrier film 303 having a thickness of 50 nm is formed on the resist film 302 by, for example, the spin coating:

Base polymer: polyvinyl hexafluoroisopropyl alcohol . . . 1 g

Solvent: n-butyl alcohol . . . 20 g

Thereafter, as shown in FIG. 5C, the resultant barrier film 303 is annealed with a hot plate at a temperature of 110° C. for 60 seconds, so as to improve the denseness of the barrier film 303.

Then, as shown in FIG. 5D, a water-repellent film of a fluorine coating film 307 with a thickness of 10 nm is formed on the barrier film 303. Specifically, the fluorine coating film 307 is obtained by applying a liquid including fluorine as a principal component, such as nonafluoro-t-butylmethyl ether or nonafluoro-t-butylethyl ether, by the spin coating. At this point, the fluorine coating film 307 may be subjected to annealing at a temperature of approximately 100° C.

Next, as shown in FIG. 6A, with an immersion liquid 304 of water provided between the fluorine coating film 307 and a projection lens 306 by, for example, the puddle method, pattern exposure is carried out by irradiating the resist film 302 through the liquid 304, the fluorine coating film 307 and the barrier film 303 with exposing light 305 of ArF excimer laser with NA of 0.68 having passed through a mask (not shown).

After the pattern exposure, as shown in FIG. 6B, the resist film 302 is baked with a hot plate at a temperature of 105° C. for 60 seconds (post exposure bake).

Next, the fluorine coating film 307 and the barrier film 303 are removed by using, for example, 1,1,2,3,3,3-hexafluoro-1-diethylamino propane, and the resultant resist film 302 is developed with a 2.38 wt % tetramethylammonium hydroxide developer. In this manner, a resist pattern 302a made of an unexposed portion of the resist film 302 and having a line width of 0.09 μm is formed in a good shape as shown in FIG. 6D.

In this manner, according to Embodiment 3, the fluorine coating film 307 having a water-repellent property is formed on the resist film 302 in the procedure for forming a water-repellent film shown in FIG. 5D. Therefore, in the procedure for pattern exposure shown in FIG. 6A, the liquid 304 can be prevented from permeating into the resist film 302 by the fluorine coating film 307 formed on the barrier film 303. Accordingly, no water mark defect is caused by the liquid 304 in the resist film 302. As a result, deterioration of the resist film 302 otherwise caused through extraction of the acid generator or the like by the liquid 304 can be prevented, so that the resultant resist pattern 302a can be formed in a good shape.

Although 1,1,2,3,3,3-hexafluoro-1-diethylamino propane is used for removing the fluorine coating film 307 and the barrier film 303 in Embodiment 3, this does not limit the invention but triethylamine tris-hydrofluoride or the like may be used instead.

EMBODIMENT 4

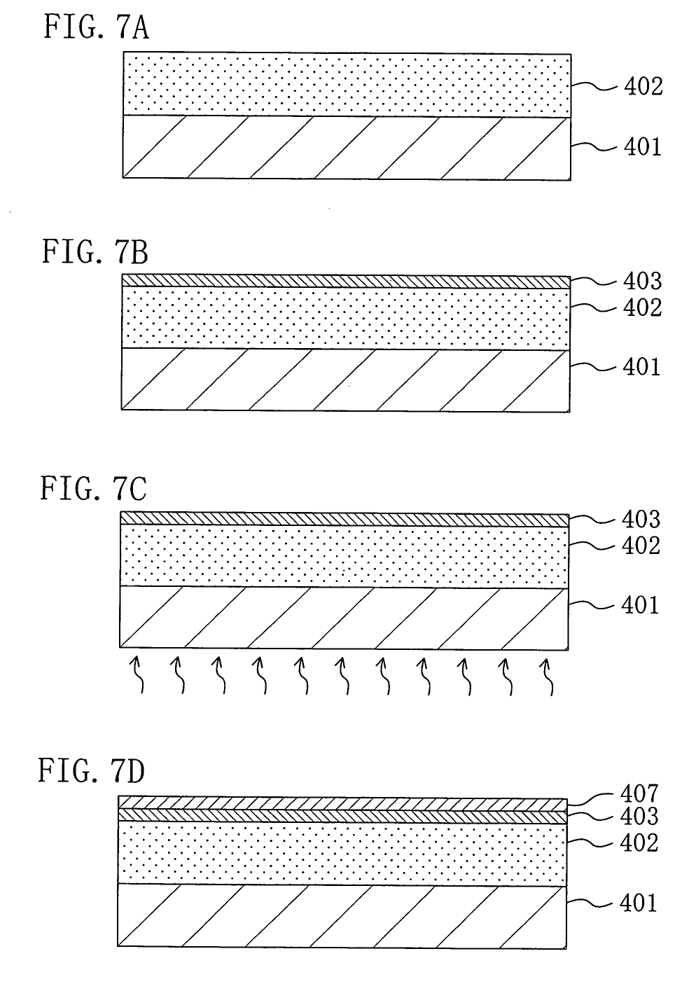

A pattern formation method according to Embodiment 4 of the invention will now be described with reference to FIGS. 7A through 7D, 8A through 8D and 9.

First, a positive chemically amplified resist material having the following composition is prepared:

Base polymer: poly((norbornene-5-methylene-t-butylcarboxylate) (50 mol %)—(maleic anhydride) (50 mol %)) . . . 2 g

Acid generator: triphenylsulfonium trifluoromethane sulfonate . . . 0.05 g

Quencher: triethanolamine . . . 0.002 g

Solvent: propylene glycol monomethyl ether acetate . . . 20 g

Next, as shown in FIG. 7A, the aforementioned chemically amplified resist material is applied on a substrate 401 so as to form a resist film 402 with a thickness of 0.35 μm.

Then, as shown in FIG. 7B, by using a conventional barrier film material having the following composition, a barrier film 403 having a thickness of 30 nm is formed on the resist film 402 by, for example, the spin coating:

Base polymer: polyvinyl hexafluoroisopropyl alcohol . . . 1 g

Solvent: n-butyl alcohol . . . 20 g

Next, as shown in FIG. 7C, the resultant barrier film 403 is annealed with a hot plate at a temperature of 110° C. for 60 seconds, so as to improve the denseness of the barrier film 403.

After the annealing, as shown in FIG. 7D, a water-repellent film 407 having a thickness of 25 nm and made of poly(tetrafluoroethylene (60 mol %)-t-butyl acrylate (40 mol %)), that is, a polymer including fluorine in a principal chain, is formed on the barrier film 403.

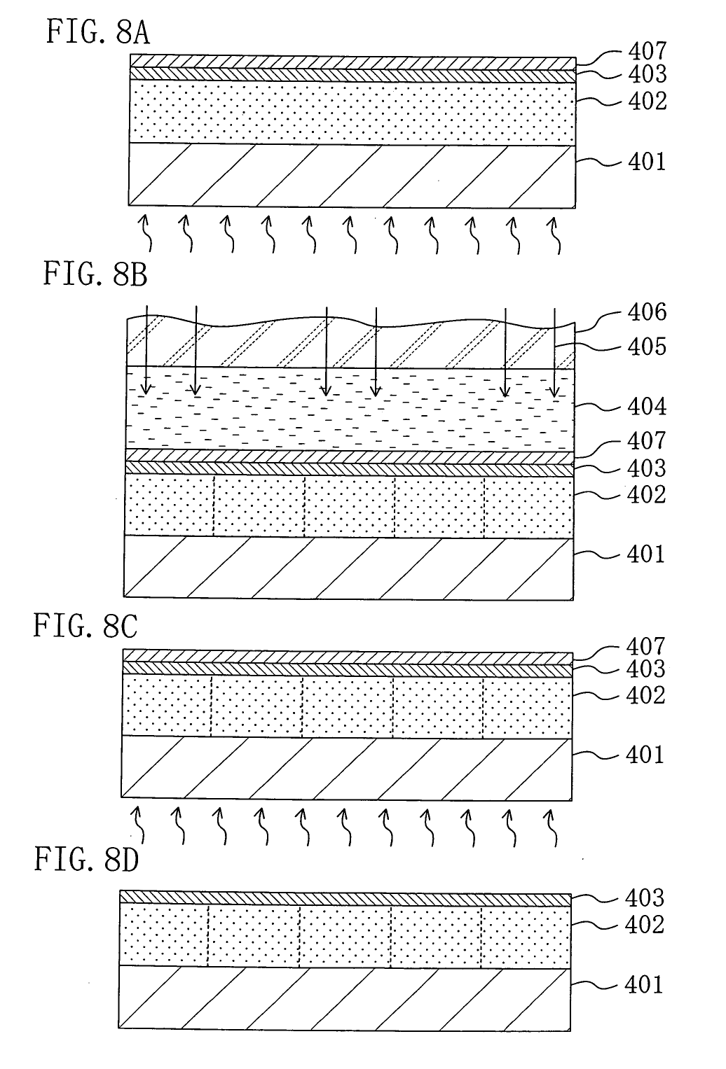

Then, as shown in FIG. 8A, the resultant water-repellent film 407 is annealed with a hot plate at a temperature of 115° C. for 60 seconds.

Next, as shown in FIG. 8B, with an immersion liquid 404 of water provided between the barrier film 403 having the water-repellent film 407 thereon and a projection lens 406 by, for example, the puddle method, pattern exposure is carried out by irradiating the resist film 402 through the liquid 404, the water-repellent film 407 and the barrier film 403 with exposing light 405 of ArF excimer laser with NA of 0.68 having passed through a mask (not shown).

After the pattern exposure, as shown in FIG. 8C, the resist film 402 is baked with a hot plate at a temperature of 105° C. for 60 seconds (post exposure bake).

Next, as shown in FIG. 8D, the water-repellent film 407 is removed by using, for example, 1,1,2,3,3,3-hexafluoro-1-diethylamino propane.

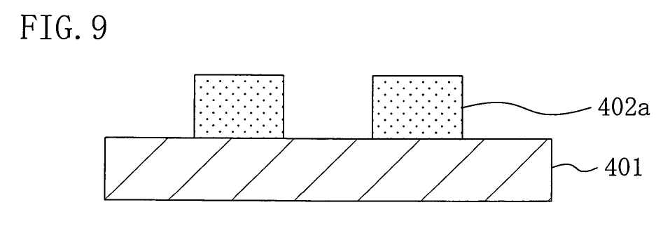

Then, the barrier film 403 is removed and the resultant resist film 402 is developed with a 2.38 wt % tetramethylammonium hydroxide developer. In this manner, a resist pattern 402a made of an unexposed portion of the resist film 402 and having a line width of 0.09 μm is formed in a good shape as shown in FIG. 9.

In this manner, according to Embodiment 4, the water-repellent film 407 having a water-repellent property and including fluorine in the principal chain is formed on the resist film 402 in the procedure for forming a water-repellent film shown in FIG. 7D. Therefore, in the procedure for pattern exposure shown in FIG. 8B, the liquid 404 can be prevented from permeating into the resist film 402 by the water-repellent film 407 formed on the barrier film 403. Accordingly, no water mark defect is caused by the liquid 404 in the resist film 402. As a result, deterioration of the resist film 402 otherwise caused through extraction of the acid generator or the like by the liquid 404 can be prevented, so that the resultant resist pattern 402a can be formed in a good shape.

Although 1,1,2,3,3,3-hexafluoro-1-diethylamino propane is used for removing the water-repellent film 407 in Embodiment 4, this does not limit the invention but triethylamine tris-hydrofluoride or the like may be used instead.

EMBODIMENT 5

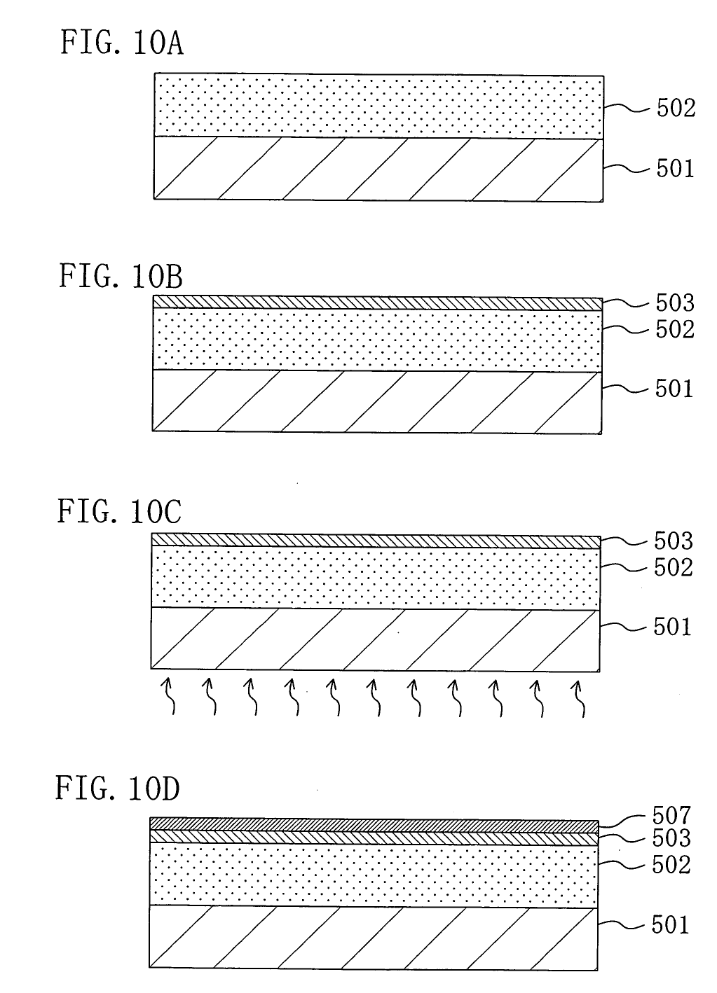

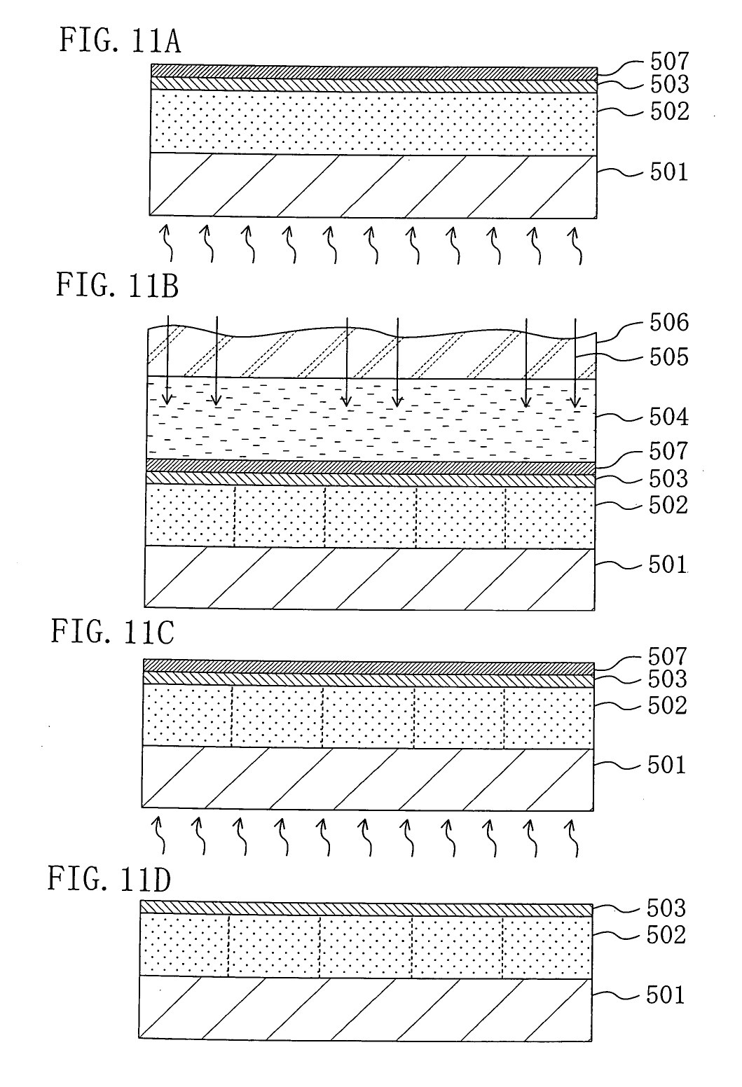

A pattern formation method according to Embodiment 5 of the invention will now be described with reference to FIGS. 10A through 10D, 11A through 11D, 12A and 12B.

First, a positive chemically amplified resist material having the following composition is prepared:

Base polymer: poly((norbornene-5-methylene-t-butylcarboxylate) (50 mol %)—(maleic anhydride) (50 mol %)) . . . 2 g

Acid generator: triphenylsulfonium trifluoromethane sulfonate . . . 0.05 g

Quencher: triethanolamine . . . 0.002 g

Solvent: propylene glycol monomethyl ether acetate . . . 20 g

Next, as shown in FIG. 10A, the aforementioned chemically amplified resist material is applied on a substrate 501 so as to form a resist film 502 with a thickness of 0.35 μm.

Then, as shown in FIG. 10B, by using a conventional barrier film material having the following composition, a barrier film 503 having a thickness of 30 nm is formed on the resist film 502 by, for example, the spin coating:

Base polymer: polyvinyl hexafluoroisopropyl alcohol . . . 1 g

Solvent: n-butyl alcohol . . . 20 g

Next, as shown in FIG. 10C, the resultant barrier film 503 is annealed with a hot plate at a temperature of 110° C. for 60 seconds, so as to improve the denseness of the barrier film 503.

After the annealing, as shown in FIG. 10D, a water-repellent film 507 having a thickness of 25 nm and made of poly(tetrafluoroethylene (60 mol %)-t-butyl acrylate (40 mol %)), that is, a polymer including fluorine in a principal chain, is formed on the barrier film 503.

Then, as shown in FIG. 11A, the resultant water-repellent film 507 is annealed with a hot plate at a temperature of 115° C. for 60 seconds.

Next, as shown in FIG. 11B, with an immersion liquid 504 of water provided between the barrier film 503 having the water-repellent film 507 thereon and a projection lens 506 by, for example, the puddle method, pattern exposure is carried out by irradiating the resist film 502 through the liquid 504, the water-repellent film 507 and the barrier film 503 with exposing light 505 of ArF excimer laser with NA of 0.68 having passed through a mask (not shown).

After the pattern exposure, as shown in FIG. 11C, the resist film 502 is baked with a hot plate at a temperature of 105° C. for 60 seconds (post exposure bake).

Next, as shown in FIG. 11D, the water-repellent film 507 is removed by using, for example, 1,1,2,3,3,3-hexafluoro-1-diethylamino propane.

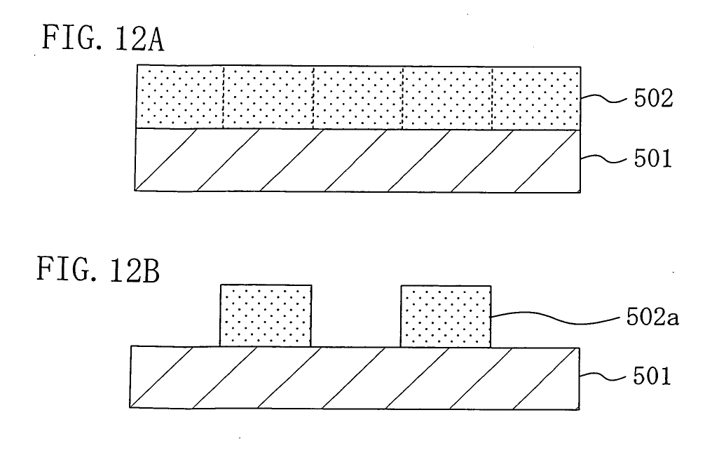

Then, as shown in FIG. 12A, the barrier film 503 is removed by using a 0.002 wt % tetramethylammonium hydroxide aqueous solution (diluted alkaline developer).

After removing the barrier film 503, the resultant resist film 502 is developed with a 2.38 wt % tetramethylammonium hydroxide developer. In this manner, a resist pattern 502a made of an unexposed portion of the resist film 502 and having a line width of 0.09 μm is formed in a good shape as shown in FIG. 12B.

In this manner, according to Embodiment 5, the water-repellent film 507 having a water-repellent property and including fluorine in the principal chain is formed on the resist film 502 in the procedure for forming a water-repellent film shown in FIG. 10D. Therefore, in the procedure for pattern exposure shown in FIG. 11B, the liquid 504 can be prevented from permeating into the resist film 502 by the water-repellent film 507 formed on the barrier film 503. Accordingly, no water mark defect is caused by the liquid 504 in the resist film 502. As a result, deterioration of the resist film 502 otherwise caused through extraction of the acid generator or the like by the liquid 504 can be prevented, so that the resultant resist pattern 502a can be formed in a good shape.

Although 1,1,2,3,3,3-hexafluoro-1-diethylamino propane is used for removing the water-repellent film 507 in Embodiment 5, this does not limit the invention but triethylamine tris-hydrofluoride or the like may be used instead.

As described above, since the barrier film 403 is removed with the developer at the same time as the development in Embodiment 4, and hence, the solubility of the resist film 402 can be controlled. On the other hand, since the barrier film 503 is removed before the development in this embodiment, the barrier film 503 can be definitely removed and hence the development can be smoothly performed.

EMBODIMENT 6

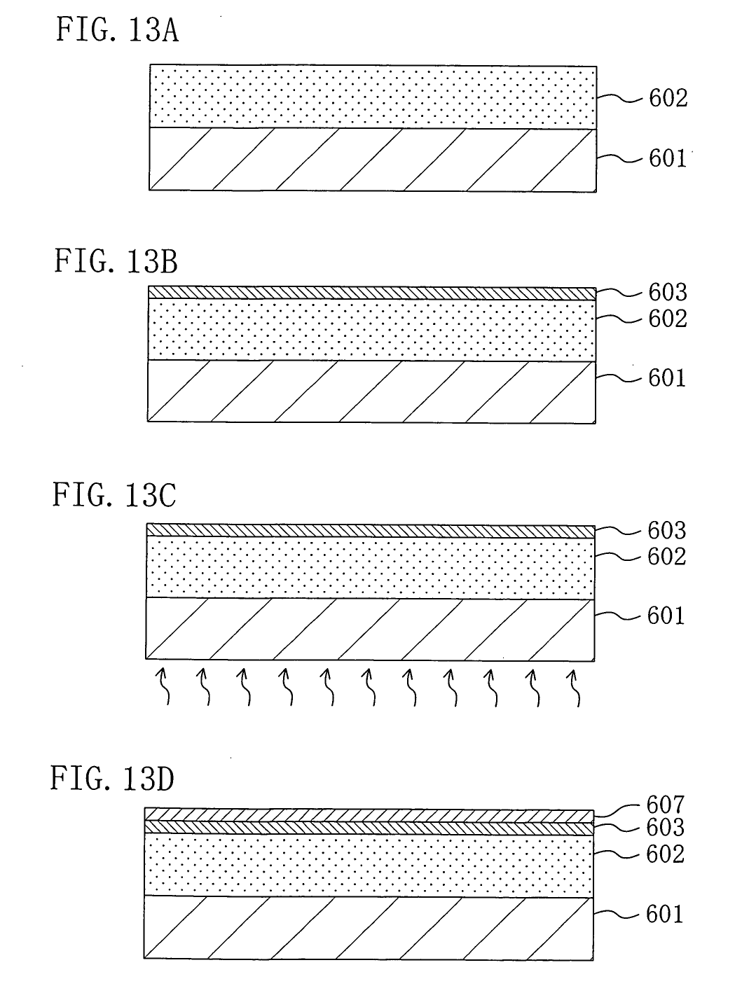

A pattern formation method according to Embodiment 6 of the invention will now be described with reference to FIGS. 13A through 13D, 14A through 14D and 15.

First, a positive chemically amplified resist material having the following composition is prepared:

Base polymer: poly((norbornene-5-methylene-t-butylcarboxylate) (50 mol %)—(maleic anhydride) (50 mol %)) . . . 2 g

Acid generator: triphenylsulfonium trifluoromethane sulfonate . . . 0.05 g

Quencher: triethanolamine . . . 0.002 g

Solvent: propylene glycol monomethyl ether acetate . . . 20 g

Next, as shown in FIG. 13A, the aforementioned chemically amplified resist material is applied on a substrate 601 so as to form a resist film 602 with a thickness of 0.35 μm.

Then, as shown in FIG. 13B, by using a conventional barrier film material having the following composition, a barrier film 603 having a thickness of 40 nm is formed on the resist film 602 by, for example, the spin coating:

Base polymer: polyvinyl hexafluoroisopropyl alcohol . . . 1 g

Solvent: n-butyl alcohol . . . 20 g

Next, as shown in FIG. 13C, the resultant barrier film 603 is annealed with a hot plate at a temperature of 110° C. for 60 seconds, so as to improve the denseness of the barrier film 603.

After the annealing, as shown in FIG. 13D, a waterproof film 607 having a thickness of 20 nm and made of a condensation polymer of ε-caprolactam, that is, polyamide, is formed on the barrier film 603.

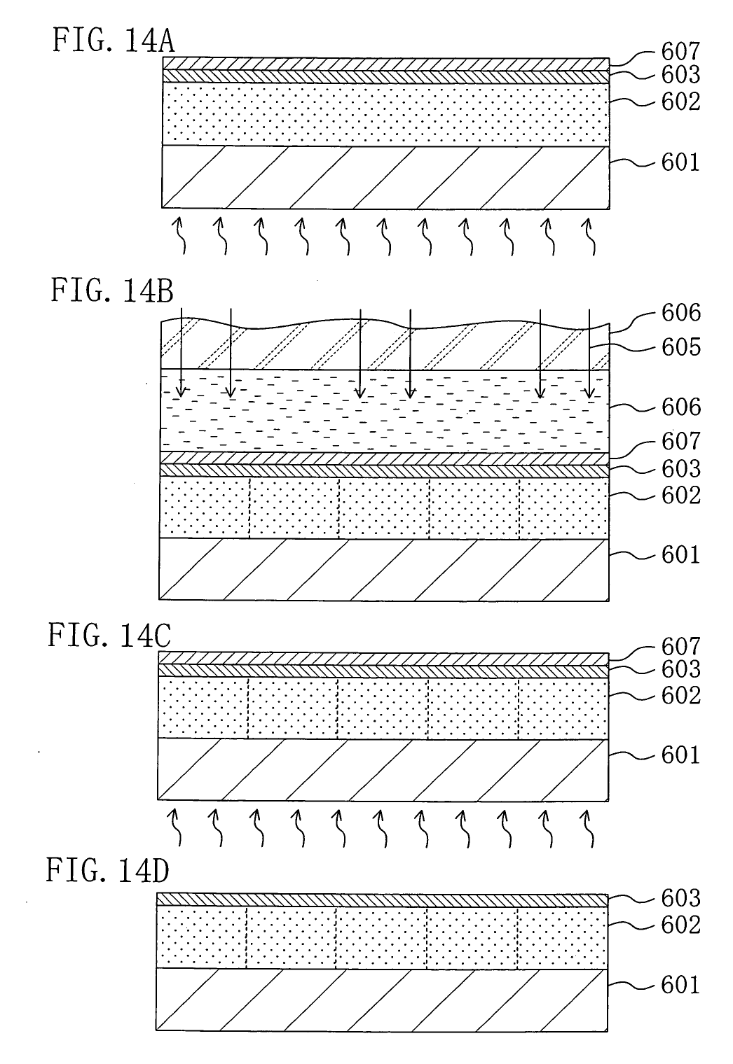

Then, as shown in FIG. 14A, the resultant waterproof film 607 is annealed with a hot plate at a temperature of 125° C. for 60 seconds.

Next, as shown in FIG. 14B, with an immersion liquid 604 of water provided between the barrier film 603 having the waterproof film 607 thereon and a projection lens 606 by, for example, the puddle method, pattern exposure is carried out by irradiating the resist film 602 through the liquid 604, the waterproof film 607 and the barrier film 603 with exposing light 605 of ArF excimer laser with NA of 0.68 having passed through a mask (not shown).

After the pattern exposure, as shown in FIG. 14C, the resist film 602 is baked with a hot plate at a temperature of 105° C. for 60 seconds (post exposure bake).

Next, as shown in FIG. 14D, the waterproof film 607 is removed by using, for example, triethylamine tris-hydrofluoride.

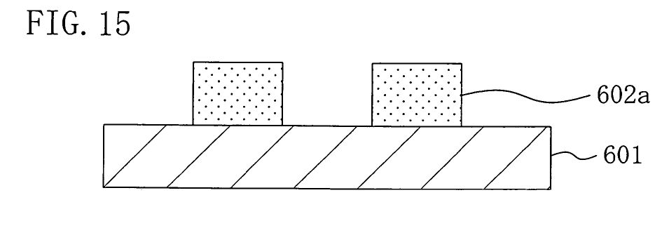

Then, the barrier film 603 is removed and the resultant resist film 602 is developed with a 2.38 wt % tetramethylammonium hydroxide developer. In this manner, a resist pattern 602a made of an unexposed portion of the resist film 602 and having a line width of 0.09 μm is formed in a good shape as shown in FIG. 15.

In this manner, according to Embodiment 6, the waterproof film 607 made of the polyamide and having a waterproof property is formed on the resist film 602 in the procedure for forming a waterproof film shown in FIG. 13D. Therefore, in the procedure for pattern exposure shown in FIG. 14B, the liquid 604 can be prevented from permeating into the resist film 602 by the waterproof film 607 formed on the barrier film 603. Accordingly, no water mark defect is caused by the liquid 604 in the resist film 602. As a result, deterioration of the resist film 602 otherwise caused through extraction of the acid generator or the like by the liquid 604 can be prevented, so that the resultant resist pattern 602a can be formed in a good shape.

Although triethylamine tris-hydrofluoride is used for removing the waterproof film 607 in Embodiment 6, this does not limit the invention but 1,1,2,3,3,3-hexafluoro-1-diethylamino propane or the like may be used instead.

EMBODIMENT 7

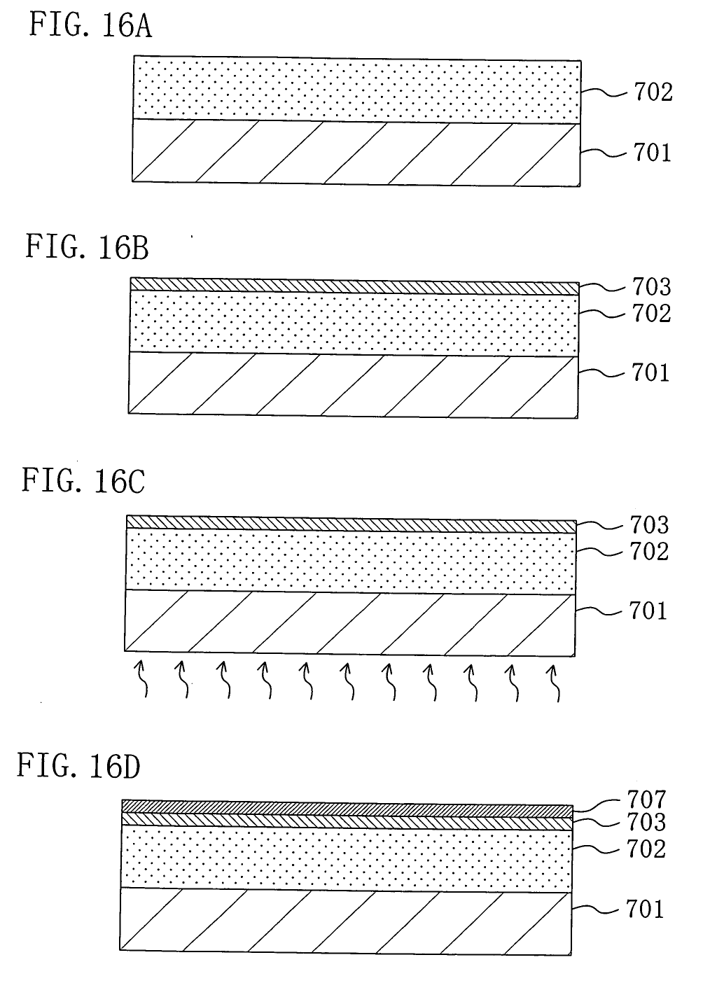

A pattern formation method according to Embodiment 7 of the invention will now be described with reference to FIGS. 16A through 16D, 17A through 17D, 18A and 18B.

First, a positive chemically amplified resist material having the following composition is prepared:

Base polymer: poly((norbornene-5-methylene-t-butylcarboxylate) (50 mol %)—(maleic anhydride) (50 mol %)) . . . 2 g

Acid generator: triphenylsulfonium trifluoromethane sulfonate . . . 0.05 g

Quencher: triethanolamine . . . 0.002 g

Solvent: propylene glycol monomethyl ether acetate . . . 20 g

Next, as shown in FIG. 16A, the aforementioned chemically amplified resist material is applied on a substrate 701 so as to form a resist film 702 with a thickness of 0.35 μm.

Then, as shown in FIG. 16B, by using a conventional barrier film material having the following composition, a barrier film 703 having a thickness of 40 nm is formed on the resist film 702 by, for example, the spin coating:

Base polymer: polyvinyl hexafluoroisopropyl alcohol . . . 1 g

Solvent: n-butyl alcohol . . . 20 g

Next, as shown in FIG. 16C, the resultant barrier film 703 is annealed with a hot plate at a temperature of 110° C. for 60 seconds, so as to improve the denseness of the barrier film 703.

After the annealing, as shown in FIG. 16D, a waterproof film 707 having a thickness of 20 nm and made of a condensation polymer of ε-caprolactam, that is, polyamide, is formed on the barrier film 703.

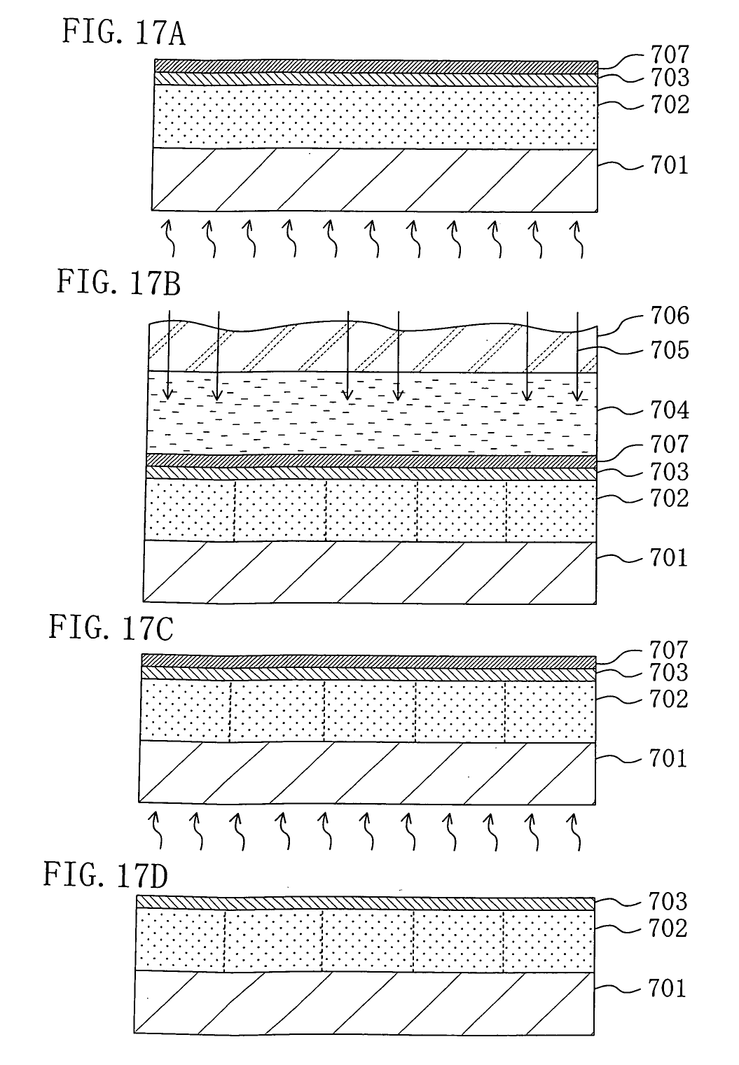

Then, as shown in FIG. 17A, the resultant waterproof film 707 is annealed with a hot plate at a temperature of 115° C. for 60 seconds.

Next, as shown in FIG. 17B, with an immersion liquid 704 of water provided between the barrier film 703 having the waterproof film 707 thereon and a projection lens 706 by, for example, the puddle method, pattern exposure is carried out by irradiating the resist film 702 through the liquid 704, the waterproof film 707 and the barrier film 703 with exposing light 705 of ArF excimer laser with NA of 0.68 having passed through a mask (not shown).

After the pattern exposure, as shown in FIG. 17C, the resist film 702 is baked with a hot plate at a temperature of 105° C. for 60 seconds (post exposure bake).

Next, as shown in FIG. 17D, the waterproof film 707 is removed by using, for example, triethylamine tris-hydrofluoride.

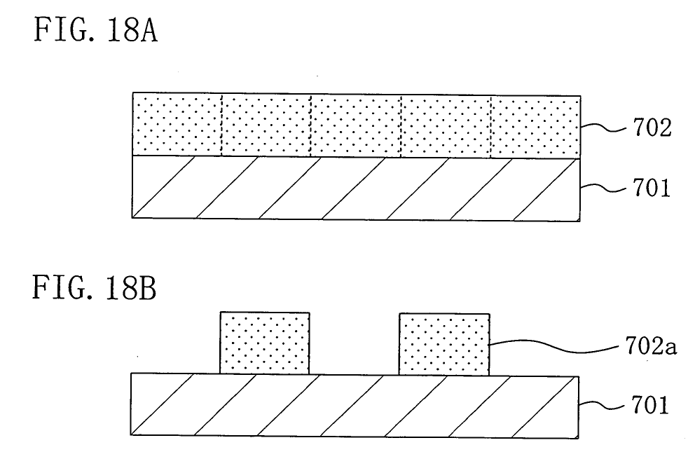

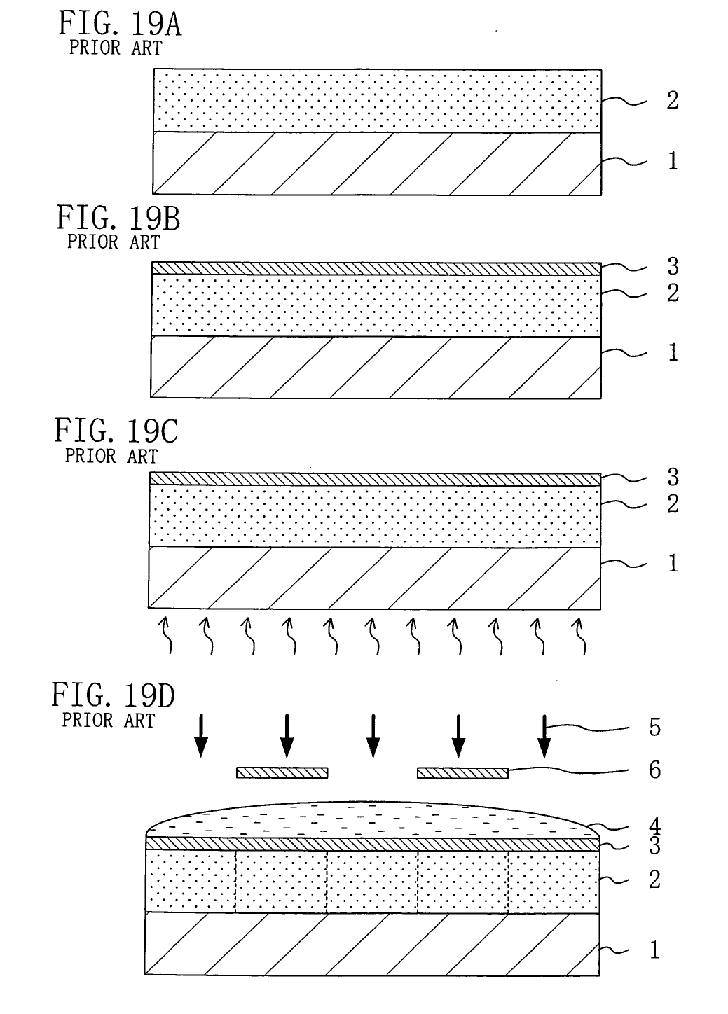

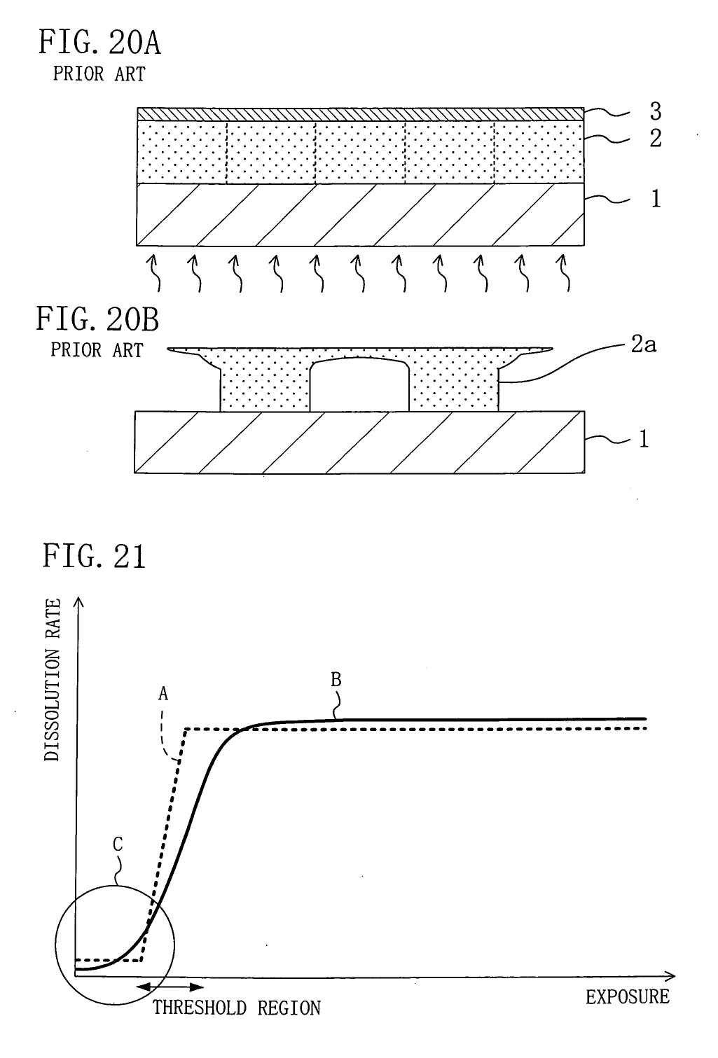

Then, as shown in FIG. 18A, the barrier film 703 is removed by using a 0.002 wt % tetramethylammonium hydroxide aqueous solution (a diluted alkaline developer).

After removing the barrier film 703, the resultant resist film 702 is developed with a 2.38 wt % tetramethylammonium hydroxide developer. In this manner, a resist pattern 702a made of an unexposed portion of the resist film 702 and having a line width of 0.09 μm is formed in a good shape as shown in FIG. 18B.

In this manner, according to Embodiment 7, the waterproof film 707 made of the polyamide and having a waterproof property is formed on the resist film 702 in the procedure for forming a waterproof film shown in FIG. 16D. Therefore, in the procedure for pattern exposure shown in FIG. 17B, the liquid 704 can be prevented from permeating into the resist film 702 by the waterproof film 707 formed on the barrier film 703. Accordingly, no water mark defect is caused by the liquid 704 in the resist film 702. As a result, deterioration of the resist film 702 otherwise caused through extraction of the acid generator or the like by the liquid 704 can be prevented, so that the resultant resist pattern 702a can be formed in a good shape.

Although triethylamine tris-hydrofluoride is used for removing the waterproof film 707 in Embodiment 7, this does not limit the invention but 1,1,2,3,3,3-hexafluoro-1-diethylamino propane or the like may be used instead.

Since the barrier film 603 is removed with the developer at the same time as the development in Embodiment 6, the solubility of the resist film 602 can be controlled. On the other hand, since the barrier film 703 is removed before the development in this embodiment, the barrier film 703 can be definitely removed and hence the development can be smoothly performed.

Although the thickness of the barrier film is 30 nm through 60 nm in each of Embodiments 1 through 7, the thickness may be not less than approximately 30 nm and not more than approximately 100 nm, which does not limit the invention.

In addition, although the barrier film is annealed for improving the denseness thereof after forming the barrier film in each embodiment, this annealing for the barrier film is not always necessary but can be appropriately performed in accordance with the composition, the thickness and the like of the barrier film.

Furthermore, cesium sulfate may be added to the immersion liquid in each of Embodiments 1 through 7, so as to increase the refractive index of the liquid. It is noted that the compound to be added for this purpose is not limited to cesium sulfate but may be phosphoric acid (H₃PO₄). Moreover, a surfactant may be further added to the immersion liquid.

Although the exposing light is ArF excimer laser in each embodiment, the exposing light is not limited to it but may be KrF excimer laser, Xe₂ laser, F₂ laser, KrAr laser or Ar₂ laser instead.

Furthermore, the puddle method is employed for providing the immersion liquid in each embodiment, which does not limit the invention, and for example, a dip method in which the whole substrate is dipped in the immersion liquid may be employed instead.

Moreover, although a positive chemically amplified resist is used for forming the resist film in each embodiment, the present invention is applicable also to a negative chemically amplified resist. Furthermore, the resist is not limited to a chemically amplified resist.

As described so far, according to the barrier film material and the pattern formation method using the same of this invention, an immersion liquid can be prevented from permeating into a resist film through a barrier film formed thereon, so that a fine resist pattern can be formed in a good shape. Accordingly, the present invention is useful as a method for forming a fine pattern to be employed in fabrication process or the like for semiconductor devices.

What is claimed is:

1. A barrier film material for use in forming a barrier film between a resist film and an immersion liquid when exposure of said resist film is performed with said immersion liquid provided above said resist film, comprising a polymer and a cross-linking agent for thermally causing a cross-linking reaction of said polymer.

2. The barrier film material of claim 1,
wherein said cross-linking agent includes a melamine compound or an epoxy compound.

3. The barrier film material of claim 1,
wherein said polymer is polyvinyl alcohol, polyacrylic acid or polyvinyl hexafluoroisopropyl alcohol.

4. A pattern formation method comprising the steps of:
forming a resist film on a substrate;
forming, on said resist film, a barrier film including a polymer and a cross-linking agent for thermally causing a cross-linking reaction of said polymer;
annealing said barrier film for cross-linking said polymer by said cross-linking agent;
performing pattern exposure by selectively irradiating said resist film through said barrier film with exposing light with a liquid provided on said barrier film;
removing said barrier film; and
forming a resist pattern made of said resist film by developing said resist film after removing said barrier film and after the pattern exposure.

5. The pattern formation method of claim 4,
wherein said cross-linking agent includes a melamine compound or an epoxy compound.

6. The pattern formation method of claim 4,
wherein said polymer is polyvinyl alcohol, polyacrylic acid or polyvinyl hexafluoroisopropyl alcohol.

7. The pattern formation method of claim 4,
wherein said liquid is water.

8. The pattern formation method of claim 4,
wherein said liquid is an acidic solution.

9. The pattern formation method of claim 8,
wherein said acidic solution is a cesium sulfate aqueous solution or a phosphoric acid aqueous solution.

10. The pattern formation method of claim 4,
wherein said exposing light is KrF excimer laser, Xe₂ laser, ArF excimer laser, F₂ laser, KrAr laser or Ar₂ laser.

11. A pattern formation method comprising the steps of:
forming a resist film on a substrate;
forming a barrier film on said resist film;
performing a water-repellent treatment for providing a water-repellent property to a surface of said barrier film;
performing pattern exposure by selectively irradiating said resist film through said barrier film with exposing light with a liquid provided on said barrier film having been subjected to the water-repellent treatment;
removing said barrier film; and
forming a resist pattern made of said resist film by developing said resist film after removing said barrier film and after the pattern exposure.

12. The pattern formation method of claim 11,
wherein said barrier film is exposed to plasma including fluorine in the step of performing a water-repellent treatment.

13. The pattern formation method of claim 11, further comprising, between the step of forming a barrier film and the step of performing pattern exposure, a step of annealing said barrier film.

14. The pattern formation method of claim 11,
wherein said liquid is water.

15. The pattern formation method of claim 11,
wherein said liquid is an acidic solution.

16. The pattern formation method of claim 15,
wherein said acidic solution is a cesium sulfate aqueous solution or a phosphoric acid aqueous solution.

17. The pattern formation method of claim 11,
wherein said exposing light is KrF excimer laser, Xe₂ laser, ArF excimer laser, F₂ laser, KrAr laser or Ar₂ laser.

18. A pattern formation method comprising the steps of:
forming a resist film on a substrate;
forming a barrier film on said resist film;
forming a water-repellent film having a water-repellent property on said barrier film;
performing pattern exposure by selectively irradiating said resist film through said water-repellent film and said barrier film with exposing light with a liquid provided on said water-repellent film;
removing said water-repellent film; and
removing said barrier film and forming a resist pattern made of said resist film by developing said resist film after removing said water-repellent film and after the pattern exposure.

19. The pattern formation method of claim 18,
wherein said barrier film is coated with a material including fluorine in the step of forming a water-repellent film.

20. The pattern formation method of claim 18,
wherein said water-repellent film includes a polymer having fluorine in a principal chain.

21. The pattern formation method of claim 20,
wherein said polymer is a copolymer of tetrafluoroethylene.

22. The pattern formation method of claim 18, further comprising, between the step of forming a barrier film and the step of performing pattern exposure, a step of annealing said barrier film.

23. The pattern formation method of claim 18,
wherein said liquid is water.

24. The pattern formation method of claim 18,
wherein said liquid is an acidic solution.

25. The pattern formation method of claim 24,
wherein said acidic solution is a cesium sulfate aqueous solution or a phosphoric acid aqueous solution.

26. The pattern formation method of claim 18,
wherein said exposing light is KrF excimer laser, Xe₂ laser, ArF excimer laser, F₂ laser, KrAr laser or Ar₂ laser.

27. A pattern formation method comprising the steps of:
forming a resist film on a substrate;
forming a barrier film on said resist film;
forming a water-repellent film having a water-repellent property on said barrier film;
performing pattern exposure by selectively irradiating said resist film through said water-repellent film and said barrier film with exposing light with a liquid provided on said water-repellent film;
removing said water-repellent film;
removing said barrier film; and
forming a resist pattern made of said resist film by developing said resist film after removing said barrier film and after the pattern exposure.

28. The pattern formation method of claim 27,
wherein said barrier film is coated with a material including fluorine in the step of forming a water-repellent film.

29. The pattern formation method of claim 27,
wherein said water-repellent film includes a polymer having fluorine in a principal chain.

30. The pattern formation method of claim 29,
wherein said polymer is a copolymer of tetrafluoroethylene.

31. The pattern formation method of claim 27, further comprising, between the step of forming a barrier film and the step of performing pattern exposure, a step of annealing said barrier film.

32. The pattern formation method of claim 27,
wherein said liquid is water.

33. The pattern formation method of claim 27,
wherein said liquid is an acidic solution.

34. The pattern formation method of claim 33,
wherein said acidic solution is a cesium sulfate aqueous solution or a phosphoric acid aqueous solution.

35. The pattern formation method of claim 27,
wherein said exposing light is KrF excimer laser, Xe₂ laser, ArF excimer laser, F₂ laser, KrAr laser or Ar₂ laser.

36. A pattern formation method comprising the steps of:
forming a resist film on a substrate;
forming a barrier film on said resist film;
forming a waterproof film having a waterproof property on said barrier film;
performing pattern exposure by selectively irradiating said resist film through said waterproof film and said barrier film with exposing light with a liquid provided on said waterproof film;
removing said waterproof film; and
removing said barrier film and forming a resist pattern made of said resist film by developing said resist film after removing said waterproof film and after the pattern exposure.

37. The pattern formation method of claim 36,
wherein said waterproof film includes polyamide.

38. The pattern formation method of claim 37,
wherein said polyamide is a condensation polymer of ε-caprolactam, a co-condensation polymer of hexamethylene diamine and adipic acid or a co-condensation polymer of p-phenylene diamine and terephthalic acid.

39. The pattern formation method of claim 36, further comprising, between the step of forming a barrier film and the step of performing pattern exposure, a step of annealing said barrier film.

40. The pattern formation method of claim 36,
wherein said liquid is water.

41. The pattern formation method of claim 36,
wherein said liquid is an acidic solution.

42. The pattern formation method of claim 41,
wherein said acidic solution is a cesium sulfate aqueous solution or a phosphoric acid aqueous solution.

43. The pattern formation method of claim 36,
wherein said exposing light is KrF excimer laser, Xe₂ laser, ArF excimer laser, F₂ laser, KrAr laser or Ar₂ laser.

44. A pattern formation method comprising the steps of:
forming a resist film on a substrate;
forming a barrier film on said resist film;
forming a waterproof film having a waterproof property on said barrier film;
performing pattern exposure by selectively irradiating said resist film through said waterproof film and said barrier film with exposing light with a liquid provided on said waterproof film;
removing said waterproof film;
removing said barrier film; and
forming a resist pattern made of said resist film by developing said resist film after removing said barrier film and after the pattern exposure.

45. The pattern formation method of claim 44,
wherein said waterproof film includes polyamide.

46. The pattern formation method of claim 45,
wherein said polyamide is a condensation polymer of ε-caprolactam, a co-condensation polymer of hexamethylene diamine and adipic acid or a co-condensation polymer of p-phenylene diamine and terephthalic acid.

47. The pattern formation method of claim 44, further comprising, between the step of forming a barrier film and the step of performing pattern exposure, a step of annealing said barrier film.

48. The pattern formation method of claim 44,
wherein said liquid is water.

49. The pattern formation method of claim 44,
wherein said liquid is an acidic solution.

50. The pattern formation method of claim 49,
wherein said acidic solution is a cesium sulfate aqueous solution or a phosphoric acid aqueous solution.

51. The pattern formation method of claim 44,
wherein said exposing light is KrF excimer laser, Xe₂ laser, ArF excimer laser, F₂ laser, KrAr laser or Ar₂ laser.
